(19) United States
(12) Patent Application Publication
(10) Pub. No.: US 2011/0004810 A1
(43) Pub. Date: Jan. 6, 2011

(54) Method and System of Receiving Data with Enhanced Error Correction

(75) Inventors: TIEN-JU TSAI, TAINAN (TW); SHIANG-LUN KAO, TAINAN (TW)

Correspondence Address: STOUT, UXA, BUYAN & MULLINS LLP, 4 VENTURE, SUITE 300, IRVINE, CA, 92618, US

(73) Assignee: HIMAX MEDIA SOLUTIONS, INC., TAINAN (TW)

(21) Appl. No.: 12/498,345

(22) Filed: Jul. 6, 2009

(51) Int. Cl. H03M 13/45; G06F 11/10

(52) U.S. Cl. 714/780; 714/777; 714/E11.032

(57) ABSTRACT

A method and system of receiving data with enhanced error correction is disclosed. One or more reliability bits associated with each received data bit are generated, for example, by a soft-decision slicer. Subsequently, one or more errors of the data bits may be corrected according to the associated reliability bit(s).

### BACKGROUND OF THE INVENTION

1. Field of the Invention

The present invention generally relates to error control, and more particularly to correcting errors with reliability information.

2. Description of the Prior Art

In a conventional analog broadcast television system, such as a NTSC (National Television System Committee), PAL (Phase Alternating Line) or SECAM (Séquentiel couleur à mémoire or Sequential Color with Memory) type, transmitted video consists of a sequence of still pictures or frames. For instance, the NTSC format specifies about 30 frames per second, and the PAL/SECAM format specifies 25 frames per second. Each frame consists of hundreds of horizontal scan lines. For instance, each frame in the NTSC format consists of 525 scan lines, among which the odd-numbered lines form an odd field and the even-numbered lines form an even field. The scan lines in each frame consist of not only video information but also vertical synchronization information, which is transmitted during a vertical blanking interval (VBI). For example, the scan lines 1-22 in the NTSC format are vertical-sync lines for the odd field, and the scan lines 263-285 are vertical-sync lines for the even field. The vertical-sync lines are used for synchronization and equalization, while carrying no video information.

The VBI is needed in conventional analog broadcast television systems for allowing magnetic coils to deflect electron beams vertically in a cathode ray tube (CRT). Although no such need exists in modern digital televisions, the VBI, nonetheless, has remained, with such modern digital broadcast television systems utilizing it for purposes such as carrying digital data, or datacasting, such that extra information other than the video information may be provided to viewers. Various types of information may be broadcasted during the VBI, such as Teletext, Vertical Interval Time Code (VITC), close captioning (CC), Copy Generation Management System (CGMS), Widescreen Signaling (WSS) or Video Programming System (VPS) content.

At the receiving end (e.g., a digital television), a demodulator recovers information from a modulated carrier radio-frequency waveform, followed by a decoder retrieving the video and the VBI data. Specifically, the receiver (e.g., the digital television) performs, in the physical layer of the Open Systems Interconnection (OSI) model, logic value recovering and bit reorganization on the received bitstream. Subsequently, the receiver performs, in the data link layer of the OSI model, error control and protocol parsing. Hamming code, cyclic redundancy check (CRC) and odd parity are commonly used in the error control processing to detect or even correct errors present in corrupted signals.

However, the error control schemes mentioned above have limited capacity for maintaining data integrity. For example, the odd parity technique can detect bit errors but cannot correct the detected error(s). The Hamming code approach, for example, can detect up to two bit errors and correct one bit error only. As a result, the VBI data cannot be correctly retrieved across noisy channels in a resource-limited receiver without resorting to more complicated, and thus more expensive, error control schemes.

For the reason that conventional digital receivers cannot satisfactorily retrieve the VBI data in environments with low signal-to-noise ratio, a need has arisen to propose a novel scheme that is capable of effectively and economically retrieving data (e.g., the VBI data).

### SUMMARY OF THE INVENTION

It is an object of the present embodiment to provide a method and system of processing data with enhanced error correction such that the data may be correctly received in an effective and economical manner.

According to one embodiment, a soft-decision slicer generates reliability bits associated with each received data bit. After the data bits are packed into a data word, an error correction control (ECC) processor detects or corrects error(s) of the data word, for example, using Hamming code, parity code or cyclic redundancy check (CRC). Subsequently, an enhanced bit error corrector corrects error(s) of the data bits according to the associated reliability bits.

### BRIEF DESCRIPTION OF THE DRAWINGS

FIG. 1 is a block diagram illustrating a system for receiving data with enhanced error correction according to one embodiment of the present invention;

FIGS. 2A through 2D show exemplary waveforms of input data;

FIGS. 3A and 3B show detailed circuits of the soft-decision slicer;

FIG. 4 shows a detailed circuit of the serial-to-parallel converter;

FIGS. 5A through 5D show flow charts illustrating the steps of detecting/correcting error of the MSBs of the data word (Word0);

FIGS. 6A through 6F are flow charts illustrating the steps of correcting error of the MSBs of the first codeword (Word1) according to reliability information;

FIG. 7A shows the waveform and corresponding signals of an error-free codeword;

FIG. 7B shows the waveform and corresponding signals of a single error-corrupted codeword;

FIG. 7C shows the waveform and corresponding signals of a multiple error-corrupted codeword; and

FIG. 7D shows the waveform and corresponding signals of an error-corrupted codeword.

### DETAILED DESCRIPTION OF THE INVENTION

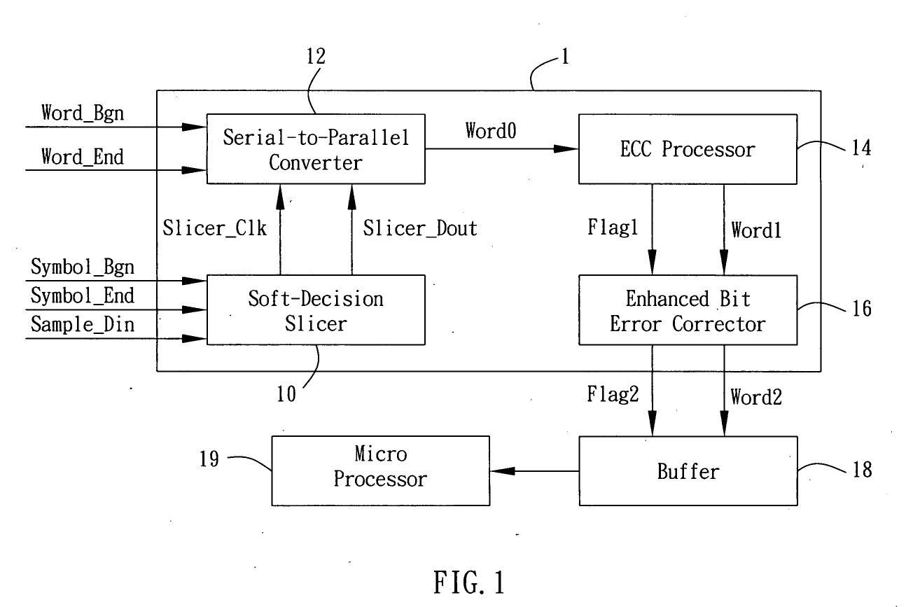

FIG. 1 is a block diagram illustrating a system 1 for receiving data with enhanced error correction according to one embodiment of the present invention. Although the system 1 illustrated here is used in retrieving vertical blanking interval (VBI) data in a digital receiver (e.g., a digital television), the embodiment may be well adopted to a general receiver in telecommunication. In the embodiment, the system 1 includes a soft-decision slicer 10, a serial-to-parallel converter 12, an error correction control (ECC) processor 14, and an enhanced bit error corrector 16. Although Hamming code, cyclic redundancy check (CRC) and odd parity are implemented in the illustrated embodiment, it is appreciated by those skilled in the pertinent art that other error correction codes or techniques may be adopted to the present invention.

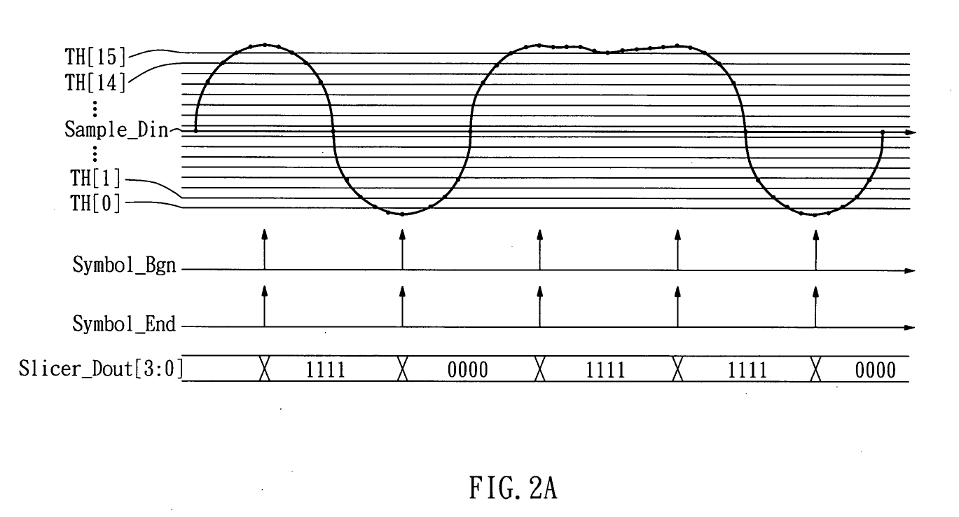

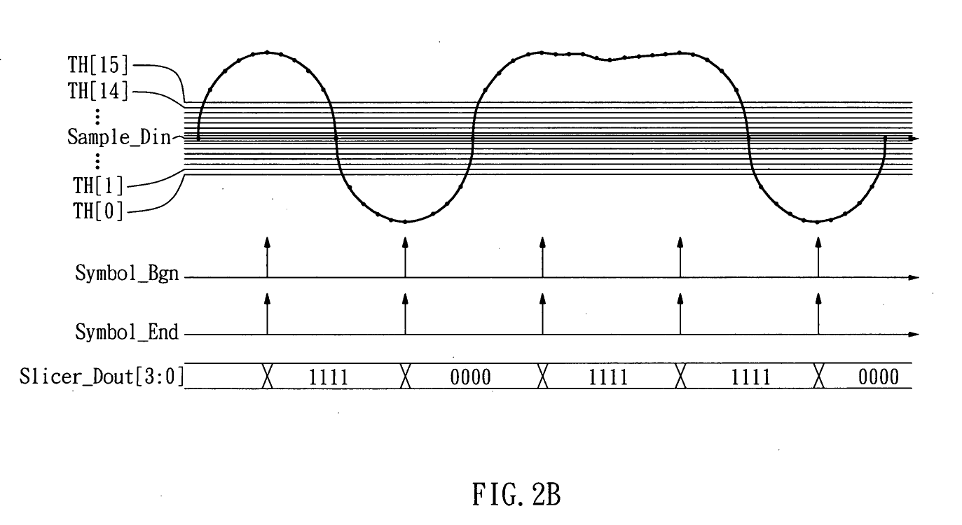

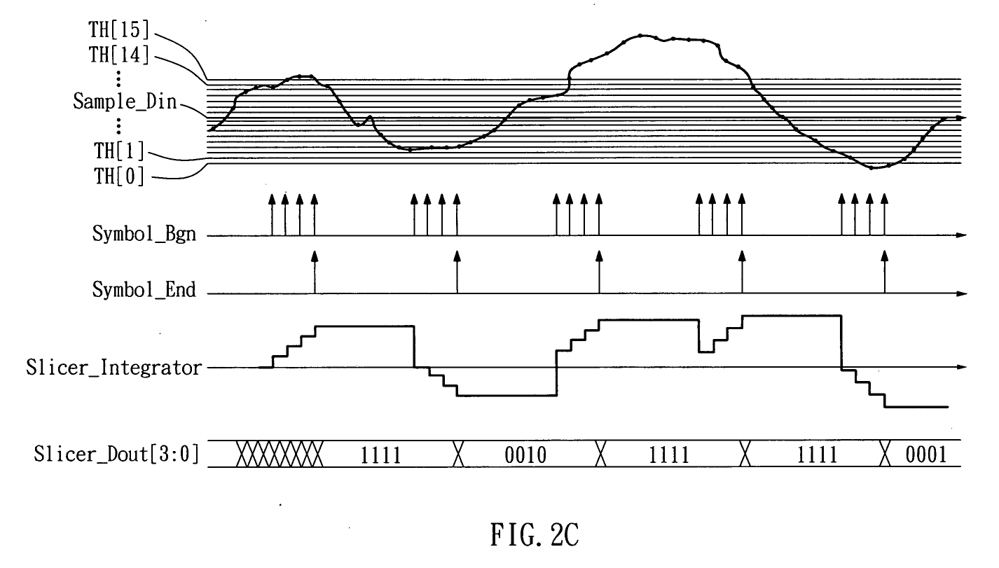

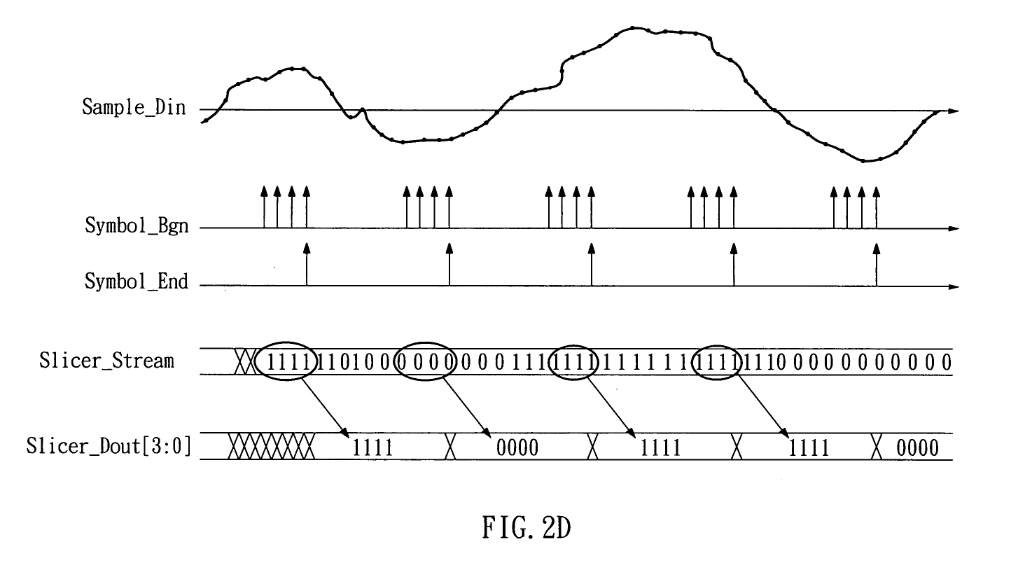

The soft-decision slicer 10 receives input data (Sample_Din) such as the waveform shown in FIG. 2A, in which data bits 1, 0, 1, 1, 0 are received in sequence. TH[0] to TH[15] represent quantization levels 0000 to 1111. Due to the soft-decision slicer 10, each slicer output (Slicer_Dout) of the slicer 10 includes multiple bits (four bits in this embodiment) rather than the original one-bit input data (Sample_Din). FIG. 2B shows another similar data waveform with quantization levels compressed near the middle.

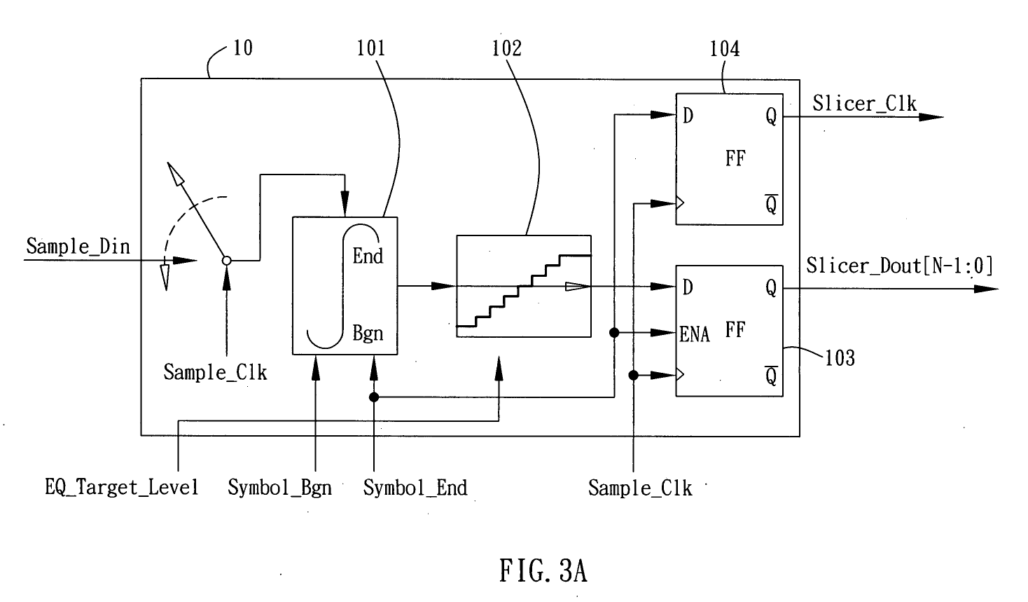

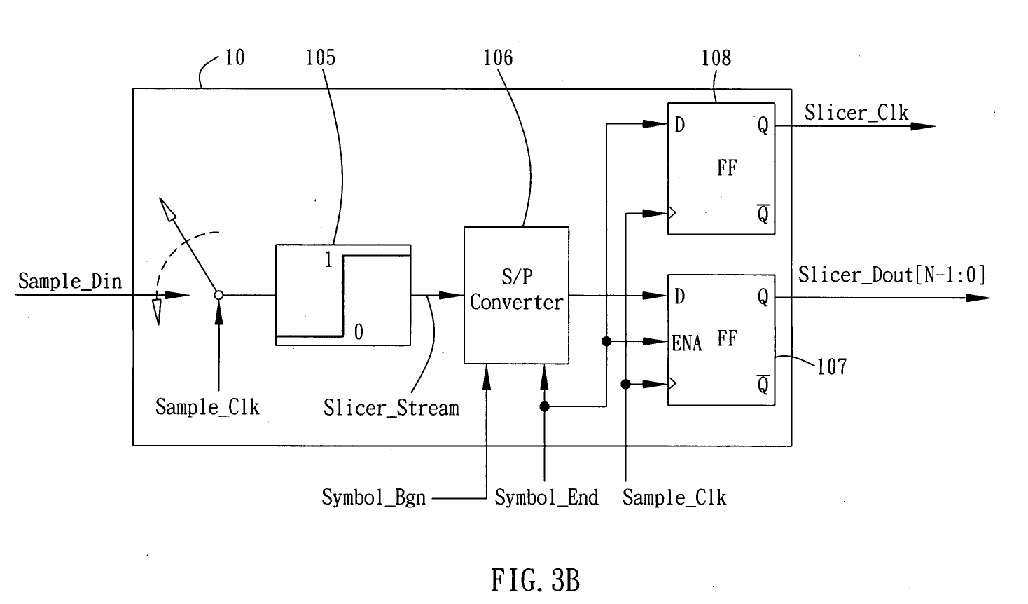

FIG. 3A shows a detailed circuit of the soft-decision slicer 10. Specifically, the input data (Sample_Din) are intermittently sampled under a sampling clock (Sample_Clk), for example by a sampling switch. The sampled data are then integrated by an integrator 101. The integrated output is usually normalized before forwarding to a quantizer 102. The output of the quantizer 102 (e.g., four-bit output in the embodiment) is collected, as the slicer output (Slicer_Dout), by flip-flop 103, before sending to the serial-to-parallel converter 12. At the same time, a clock (Slicer_Clk) corresponding to timing of the slicer output (Slicer_Dout) is also generated by another flip-flop 104. If the control signals Symbol_Bgn and Symbol_End that control the beginning and the end of the integrator 101 coincide with each other such as with the situation shown in FIG. 2A or 2B, the integrator 101 in fact does not perform integration. FIG. 2C shows a situation in which the control signals Symbol_Bgn and Symbol_End do not coincide. As shown in FIG. 2C, four samples are (over) sampled and integrated between (and including) the Symbol_Bgn and Symbol_End. After the integrated output is normalized (or divided by four in this example), the output of the quantizer 102 is generated as the slicer output (Slicer_Dout).

FIG. 3B shows another detailed circuit of the soft-decision slicer 10. Specifically, the input data (Sample_Din) are intermittently sampled under the sampling clock (Sample_Clk). Each sampled datum is hard-decided to be either “1” or “0” by a hard-decision slicer 105. The hard-decided outputs (Slicer_Stream) are converted into parallel form by a serial-to-parallel converter 106. The outputs of the serial-to-parallel converter 106 are collected, as the slicer output (Slicer_Dout), by flip-flop 107, before being sent to the serial-to-parallel converter 12. At the same time, a clock (Slicer_Clk) corresponding to the timing of the slicer output (Slicer_Dout) is also generated by another flip-flop 108. FIG. 2D shows a waveform, in which four samples are hard-decided between (and including) the control signals Symbol_Bgn and Symbol_End. The hard-decided results are then outputted as the slicer output (Slicer_Dout).

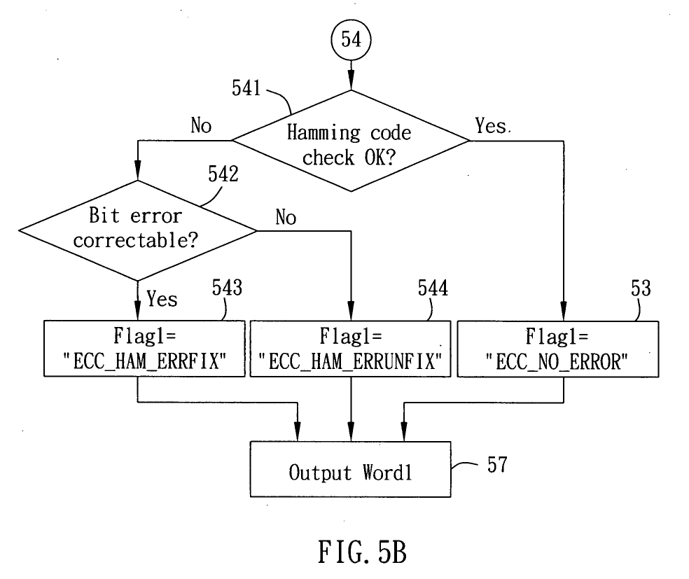

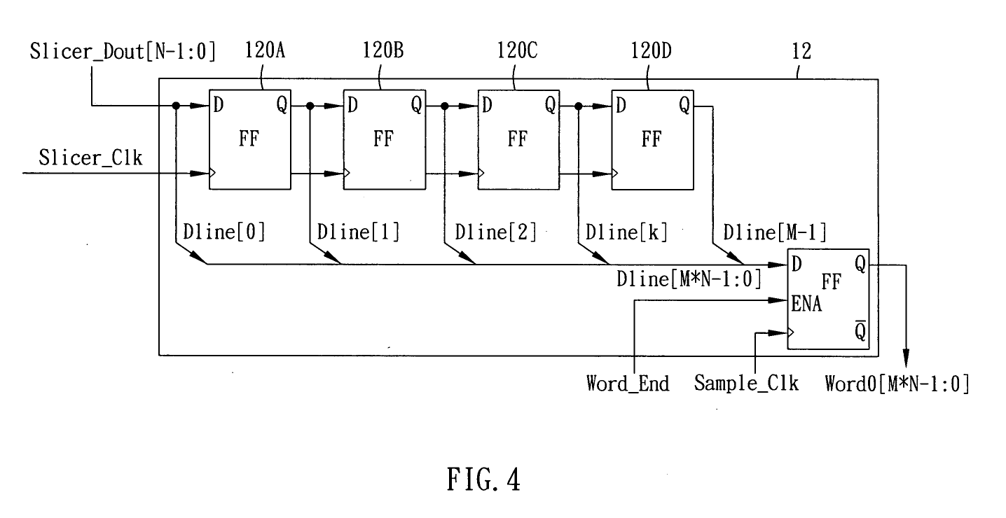

Each 4-bit slicer output (Slicer_Dout) equivalently represents one data bit of the original received input data (Sample-Din). The slicer outputs (Slicer_Dout) are forwarded in sequence to the serial-to-parallel converter 12, which packs, for example, eight slicer outputs (Slicer_Dout) into one data word (Word0), under control of control signals Word_Bgn and Word_end. FIG. 4 shows a detailed circuit of the serial-to-parallel converter 12. In the embodiment, the serial-to-parallel converter 12 uses four serial-connected flip-flops 120A-120D to generate parallel data word (Word0).

According to one aspect of the present embodiment, the most significant bit (MSB) of the 4-bit slicer output (Slicer_Dout) represents the data bit of the original input data (Sample_Din). The other bits in the slicer output (Slicer_Dout) contain reliability information (or weighting), and may be used as reliability bits after being normalized. In the embodiment, the normalization is performed according to the rule illustrated in the following table.

TABLE 1

| Original | | | | | | | | |
|---|---|---|---|---|---|---|---|---|
| slicer output | | | | Normalized | | | | |
| | Less | | | slicer output | | | | |
| MSB | significant bits | | | MSB | Reliability bits | | | Reliability |
| 1 | 1 | 1 | 1 | 1 | 1 | 1 | 1 | Strongest “1” |
| 1 | 1 | 1 | 0 | 1 | 1 | 1 | 0 | Relatively strong “1” |
| . . . | | | | . . . | | | | |
| 1 | 0 | 0 | 1 | 1 | 0 | 0 | 1 | Relatively weak “1” |
| 1 | 0 | 0 | 0 | 1 | 0 | 0 | 0 | Weakest “1” |
| 0 | 1 | 1 | 1 | 0 | 0 | 0 | 0 | Weakest “0” |
| 0 | 1 | 1 | 0 | 0 | 0 | 0 | 1 | Relatively weak “0” |
| . . . | | | | . . . | | | | |
| 0 | 0 | 0 | 1 | 0 | 1 | 1 | 0 | Relatively strong “0” |
| 0 | 0 | 0 | 0 | 0 | 1 | 1 | 1 | Strongest “0” |

Generally speaking, when the MSB is “1” the less significant bits of the slicer output remain unchanged, and when the MSB is “0” the less significant bits of the slicer output are inverted. With respect to the normalized slicer output, the reliability bits indicate the reliability of the associated MSB data bit. For example, “1111” indicates strongest “1”; “1000” indicates weakest “1”; “0111” indicates strongest “0”; and “0000” indicates weakest “0.” The data bit with strongest reliability is assumed to be least affected by noise, while the data bit with weakest reliability is assumed to be greatly affected by noise. In the embodiment, the normalization of the reliability information is performed in the enhanced bit error corrector 16, but may be performed in other portions of the system 1. It is appreciated that the slicer output need not necessarily be normalized in other embodiments. That is, if the slicer output is not normalized, then “1111” indicates strongest “1”; “1000” indicates weakest “1”; however, “0111,” indicates weakest “0”; and “0000” indicates strongest “0.”

Subsequently, the data word (Word0) is processed by the ECC processor 14 to detect and/or correct the error(s) in the MSBs of the data word (Word0). The MSBs are detected/corrected with, for example, conventional Hamming code, CRC or odd parity algorithyms. The result of the ECC processor 14 is denoted in the first flag (Flag1). If no error is detected the first flag (Flag1) is set to “NO_ERROR”; if error is detected and corrected the first flag (Flag1) is set to “ERRFIX”; if error is detected but fails to be corrected the first flag (Flag1) is set to “ERRUNFIX”; and if error is detected but incapable of being corrected the first flag (Flag1) is set to “ERROR.” The MSBs, which are either corrected or not corrected, along with the reliability information are outputted as the first ECC codeword (Word1).

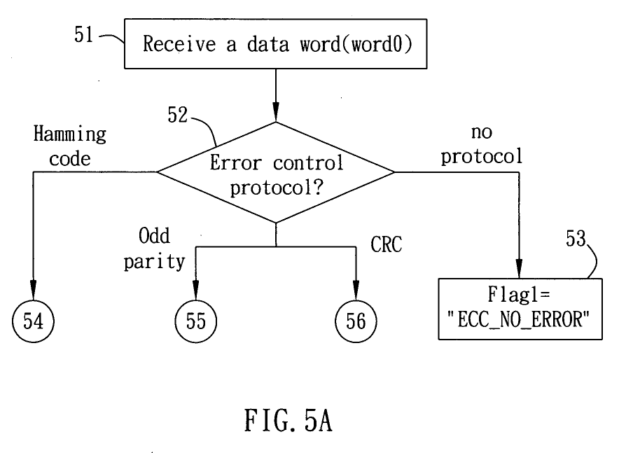

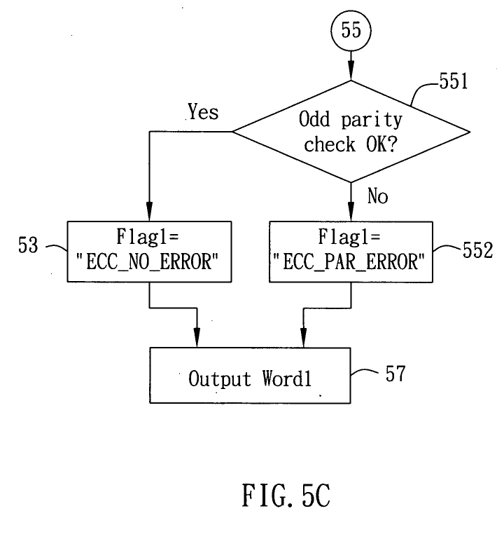

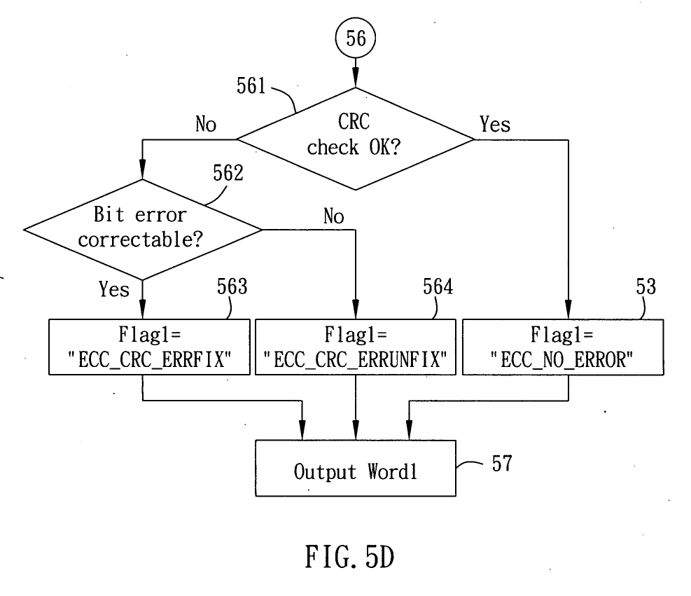

FIGS. 5A through 5D show flow charts illustrating the steps of detecting/correcting error of the MSBs of the data word (Word0). In FIG. 5A, after receiving a complete data word (Word0) (step 51), a specific error control protocol is determined in step 52. In the embodiment, the error control protocol is specified in the VBI data. If the Hamming code approach is specified the succeeding flow (54) is illustrated in FIG. 5B; if the odd parity approach is specified the succeeding flow (55) is illustrated in FIG. 5C; if the CRC approach is specified the succeeding flow (56) is illustrated in FIG. 5D; and if no protocol is specified the first flag (Flag1) is set to “ECC_NO_ERROR” (step 53).

Regarding the Hamming code, as illustrated in FIG. 5B, if the Hamming code of the data word (Word0) is checked to be OK (i.e., no error has been detected with respect to the Hamming code) in step 541 the first flag (Flag1) is set to “ECC_NO_ERROR” (step 53). Otherwise, further determination is made as to whether any bit error can be corrected (step 542). As mentioned above, the Hamming code can generally detect up to two bit errors and correct one bit error only. If the bit error is correctable the bit error is then corrected, and the first flag (Flag1) is set to “ECC_HAM_ERRFIX” (step 543). Otherwise, the first flag (Flag1) is set to “ECC_HAM_ERRUNFIX” (step 544). The MSBs, which are either corrected or not corrected, along with the reliability information are then outputted as the first ECC codeword (Word1) (step 57).

Regarding the odd parity, as illustrated in FIG. 5C, if the odd parity of the data word (Word0) is checked to be OK (i.e., no error has been detected with respect to the odd parity) in step 551 the first flag (Flag1) is set to “ECC_NO_ERROR” (step 53). Otherwise, the first flag (Flag1) is set to “ECC_PAR_ERROR” (step 552). As mentioned above, odd parity can detect bit error(s) but cannot correct the detected error(s). The MSBs along with the reliability information are then outputted as the first ECC codeword (Word1) (step 57).

Regarding the CRC, as illustrated in FIG. 5D, if the CRC of the data word (Word0) is checked to be OK (i.e., no error has been detected with respect to the CRC) in step 561 the first flag (Flag1) is set to “ECC_NO_ERROR” (step 53). Otherwise, further determine whether any bit error can be corrected (step 562). If the bit error is correctable, the bit error is then corrected and the first flag (Flag1) is set to “ECC_CRC_ERRFIX” (step 563). Otherwise, the first flag (Flag1) is set to “ECC_CRC_ERRUNFIX” (step 564). The MSBs, which are either corrected or not corrected, along with the reliability information are then outputted as the first ECC codeword (Word1) (step 57).

Afterwards, the first codeword (Word1) and the first flag (flag1) out of the ECC processor 14 are fed to the enhanced bit error corrector 16, which further processes the MSB that is either detected but failed to be corrected (i.e., “ERRUNFIX”) or is detected but incapable of being corrected (i.e., “ERROR”) based on the associated reliability bits. After the first codeword (Word1) has been processed by the enhanced bit error corrector 16 a second flag (Flag2) is generated, and the MSBs of the processed first codeword (Word1) are extracted as the second ECC codeword (Word2), both of which are temporarily stored in a buffer 18 and then forwarded to a microprocessor 19. According to the embodiment, more bit error(s) can be further corrected according to the enhanced bit error corrector 16, resulting in the second ECC codeword (Word2) having fewer error(s).

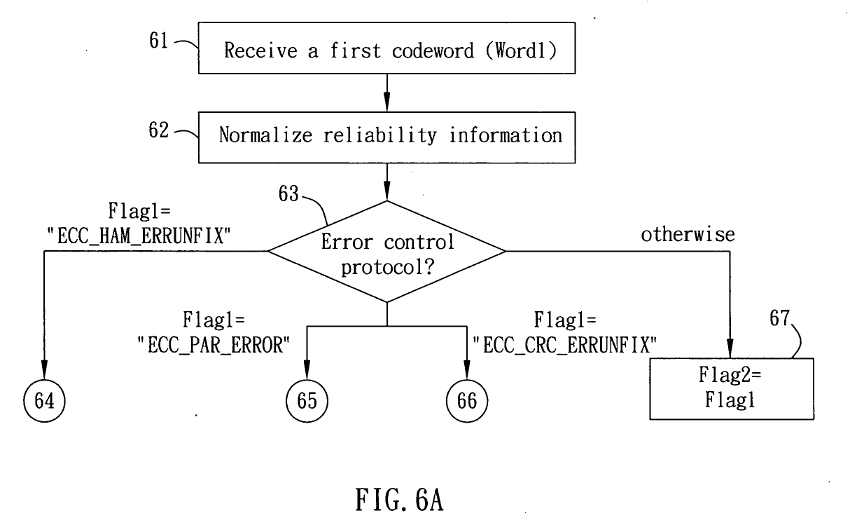

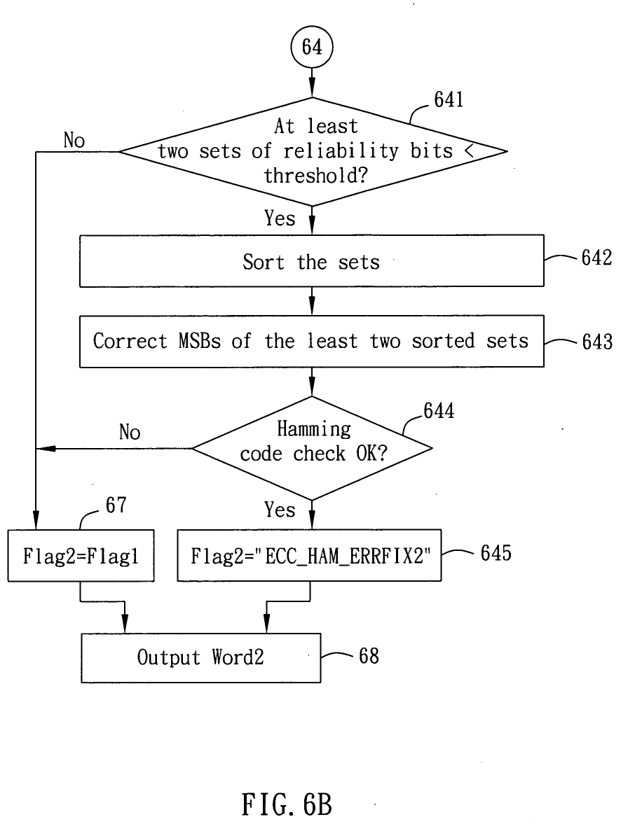

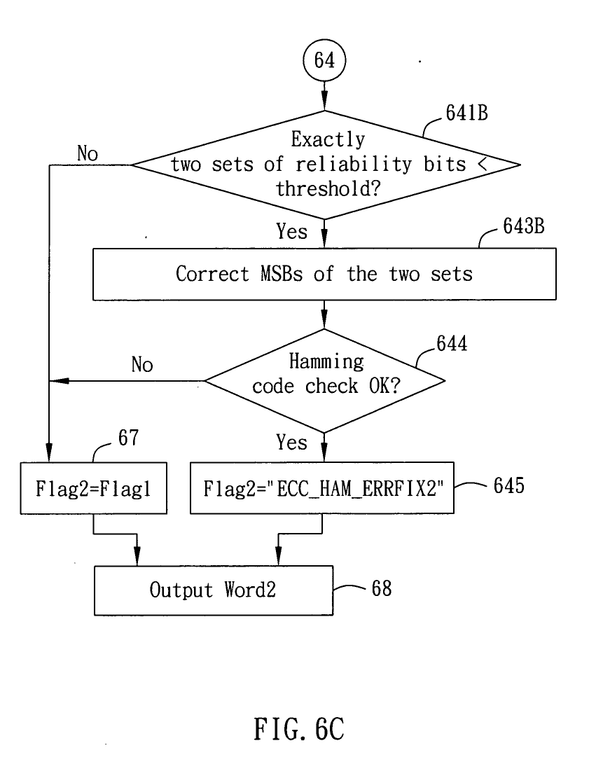

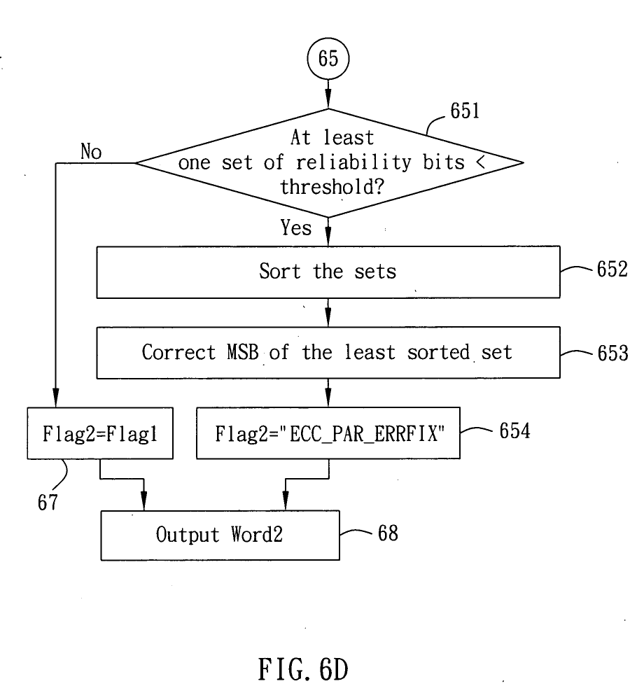

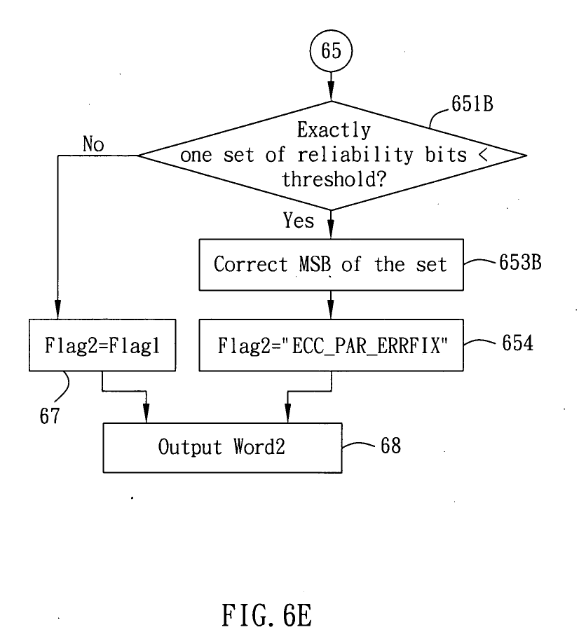

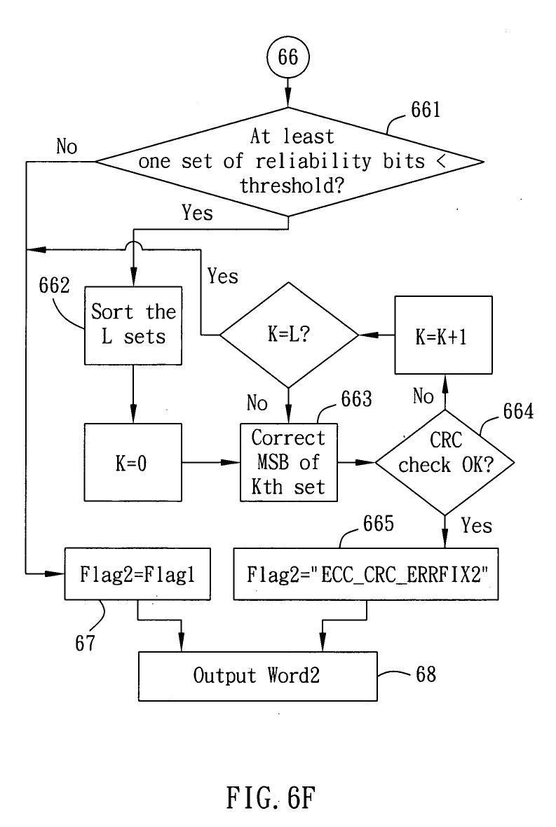

FIGS. 6A through 6F show flow charts illustrating the steps of correcting error of the MSBs of the first codeword (Word1) according to reliability information. In FIG. 6A, after receiving a complete first codeword (Word1) (step 61), the reliability information (i.e., the less significant bits of the first codeword (Word1)) is normalized (step 62), details of which have been provided above. Subsequently, the method determines whether a specific error control protocol fails to correct or is not capable of correcting the bit error (step 63). If the Hamming code fails to correct the bit error (i.e., Flgl=“ECC_HAM_ERRUNFIX”) the succeeding flow (64) is illustrated in FIG. 6B or FIG. 6C; if the odd parity is not capable of correcting the bit error (i.e., Flag1=“ECC_PAR_ERROR”) the succeeding flow (65) is illustrated in FIG. 6D or FIG. 6E; if the CRC fails to correct the bit error (i.e., Flg1=“ECC_CRC_ERRUNFIX”) the succeeding flow (66) is illustrated in FIG. 6F; otherwise the second flag (Flag2) is set according to the first flag (Flag1) (step 67).

Regarding the Hamming code, as illustrated in FIG. 6B, if there are at least two sets of normalized reliability bits each being smaller than a threshold value (step 641), the sets that are smaller than the threshold are then sorted (step 642). If step 641 is “No,” the second flag (Flag2) is set according (or equal) to the first flag (Flag1) (step 67) (i.e., the second flag (Flag2) is set to “ECC_HAM_ERRUNFIX”). The two sets whose reliability bits have least values (i.e., with weakest reliability) are assumed to have the bit error. Accordingly, the MSBs of these two sets are corrected (i.e., inverted) (step 643). The MSBs of the corrected first codeword (Word1) are checked again for the Hamming code (step 644). If the Hamming code of the first codeword (Word1) is checked to be OK (i.e., no error has been detected with respect to the Hamming code) the second flag (Flag2) is set to “ECC_HAM_ERRFIX2” (step 645). Otherwise, the second flag (Flag2) is set according to the first flag (Flag1) (step 67) (i.e., the second flag (Flag2) is set to “ECC_HAM_ERRUNFIX”). The MSBs, which are either corrected or not corrected, are then outputted as the second ECC codeword (Word2) (step 68).

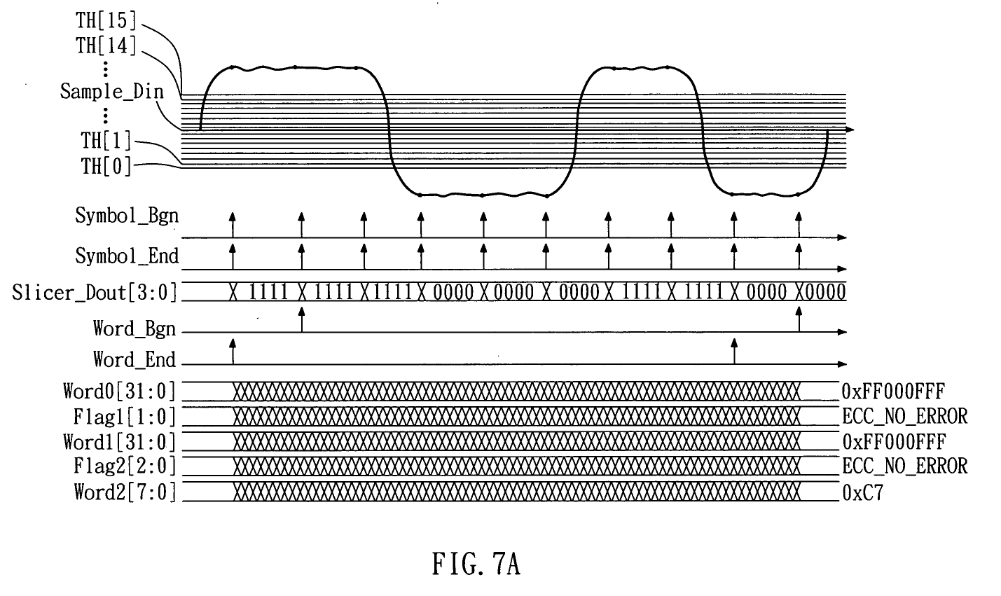

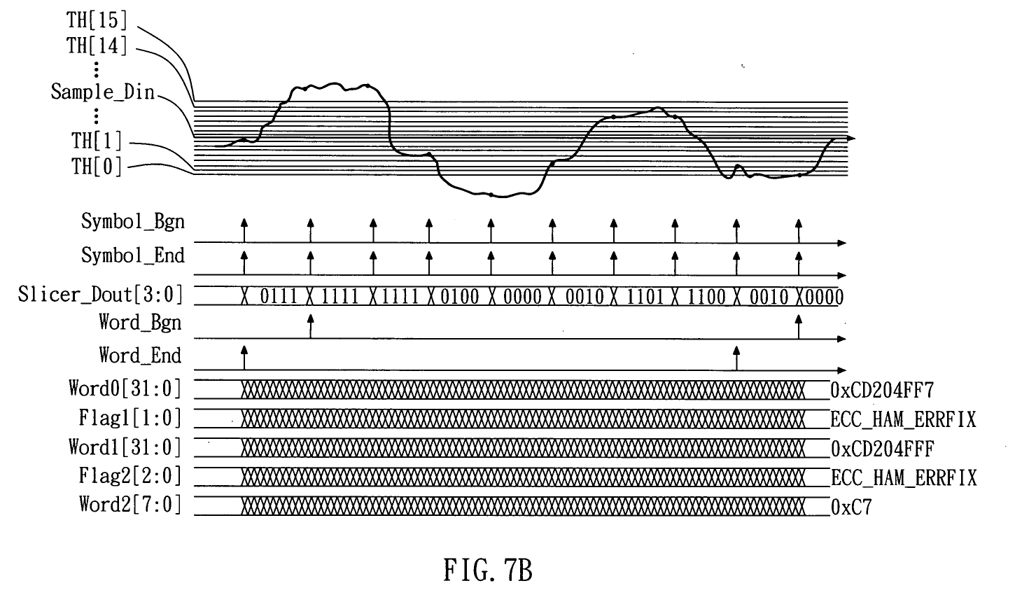

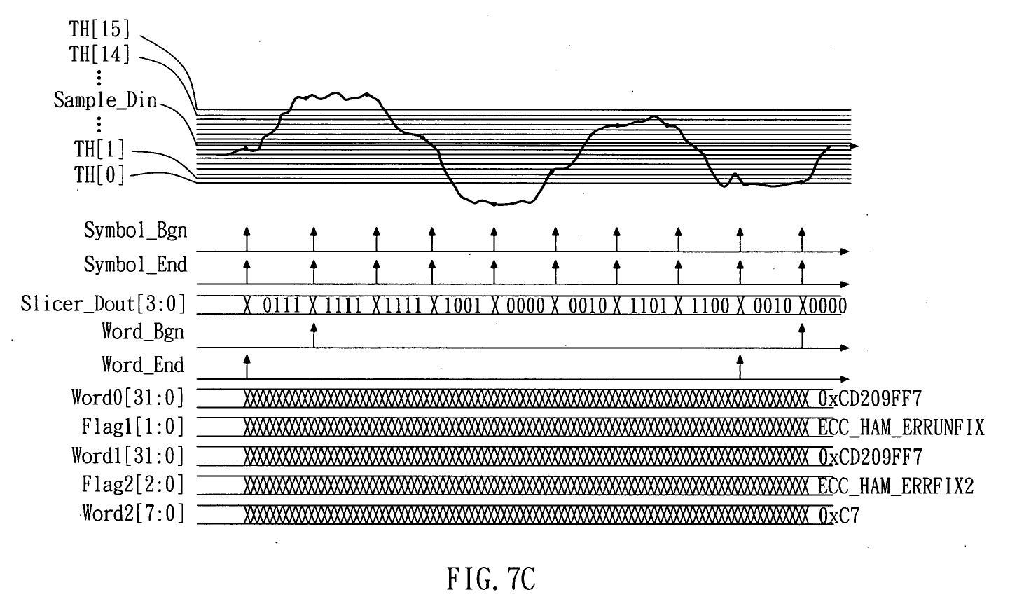

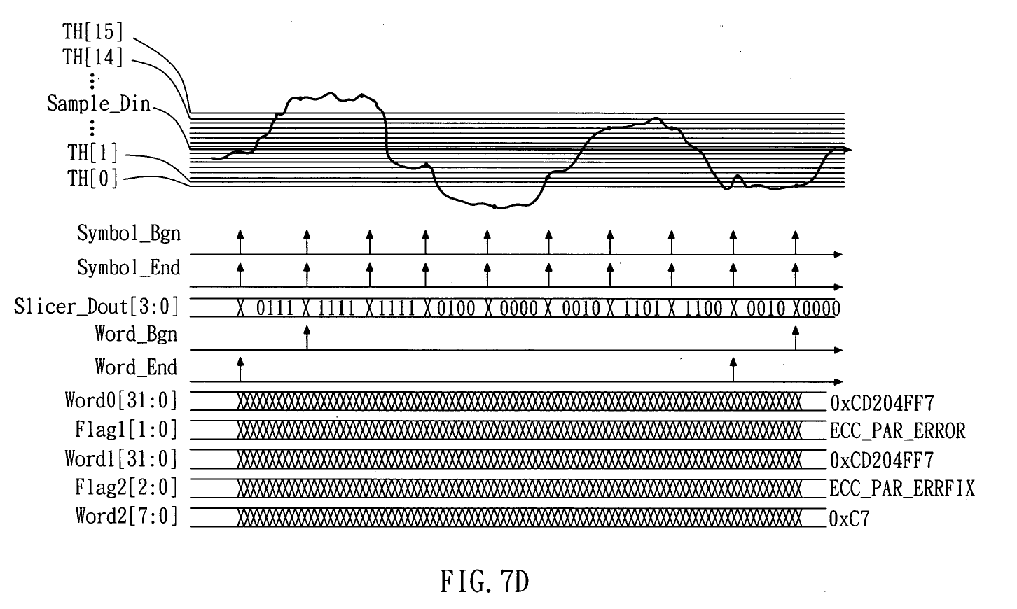

FIG. 7A shows the waveform and corresponding signals of an error-free codeword. FIG. 7B shows the waveform and corresponding signals of a single error-corrupted codeword. The single error (i.e., “0111”) in FIG. 7B can be detected and corrected with the Hamming code by the ECC processor 14. FIG. 7C shows the waveform and corresponding signals of a multiple error-corrupted codeword. The multiple error (i.e., “0111” and “1001”) can be detected but cannot be corrected with the Hamming code by the ECC processor 14. However, the multiple errors can be corrected by the enhanced bit error corrector 16. Specifically, the slicer output “0111” has the weakest normalized reliability bits “000,” and “1001” has next weakest normalized reliability bits “001.” After correcting the MSBs of these two slicer outputs with weakest reliability the codeword thus can be corrected by the enhanced bit error corrector 16.

FIG. 6C illustrates a modified flow chart of FIG. 6B. In FIG. 6C, in case of exactly two sets of normalized reliability bits each being smaller than a threshold value (step 641B), the MSBs of these two sets are corrected (i.e., inverted) (step 643B). Accordingly, no sorting need be performed in FIG. 6C. Other steps are the same as those in FIG. 6B.

Regarding the odd parity, as illustrated in FIG. 6D, if there are at least one set of normalized reliability bits each being smaller than a threshold value (step 651), the sets that are smaller than the threshold are then sorted (step 652). If step 651 is “No,” the second flag (Flag2) is set according to the first flag (Flag1) (step 67) (i.e., the second flag (Flag2) is set to “ECC_PAR_ERROR”). The one set whose reliability bits have least value (i.e., with weakest reliability) is assumed to have the bit error. Accordingly, the MSB of this set is corrected (i.e., inverted) (step 653). The second flag (Flag2) is set to “ECC_PAR_ERRFIX” (step 654). The MSBs, which are either corrected or not corrected, are then outputted as the second ECC codeword (Word2) (step 68).

FIG. 7D shows the waveform and corresponding signals of an error-corrupted codeword. One error can be detected but cannot be corrected with the odd parity by the ECC processor 14. However, the error can be corrected by the enhanced bit error corrector 16. Specifically, the slicer output “0111” has the weakest normalized reliability bits “000.” After correcting the MSBs of this slicer output with weakest reliability, the codeword thus can be corrected by the enhanced bit error corrector 16.

FIG. 6E illustrates a modified flow chart of FIG. 6D. In FIG. 6E, in case of exactly one set of normalized reliability bits being smaller than a threshold value (step 651B), the MSB of the set is corrected (i.e., inverted) (step 653B). Accordingly, no sorting need be performed in FIG. 6E. Other steps are the same as those in FIG. 6D.

Regarding the CRC, as illustrated in FIG. 6F, if there are at least one set (e.g., L sets) of normalized reliability bits each being smaller than a threshold value (step 661), the sets that are smaller than the threshold are then sorted (step 662). If step 661 is “No,” the second flag (Flag2) is set according to the first flag (Flag1) (step 67) (i.e., the second flag (Flag2) is set to “ECC_CRC_ERRUNFIX”). The MSBs of these sorted L sets are corrected (i.e., inverted) one set at a time (step 663) from the least reliability value (i.e., when K=0) to the most reliability value (i.e., when K=L−1). After correcting the MSB at each time, the MSBs of the corrected first codeword (Word1) are checked for the CRC (step 664). If the CRC of the corrected first codeword (Word1) is checked to be OK (i.e., no error has been detected with respect to the CRC) the second flag (Flag2) is set to “ECC_CRC_ERRFIX2” (step 665). Otherwise, the MSB of next (i.e., (K+1)-th) sorted set is corrected (step 663), followed by checking the MSBs of the corrected first codeword (Word1) (step 664). If all L sets are checked not to be OK, the second flag (Flag2) is set according to the first flag (Flag1) (step 67) (i.e., the second flag (Flag2) is set to “ECC_CRC_ERRUNFIX”). The MSBs, which are either corrected or not corrected, are then outputted as the second ECC codeword (Word2) (step 68).

Although specific embodiments have been illustrated and described, it will be appreciated by those skilled in the art that various modifications may be made without departing from the scope of the present invention, which is intended to be limited solely by the appended claims.

What is claimed is:

1. A method of receiving data with enhanced error correction, comprising:
generating at least one reliability bit associated with each received data bit; and
correcting at least one error of the data bit according to the associated at least one reliability bit.

2. The method of claim 1, wherein the error is corrected with Hamming code, parity code or cyclic redundancy check (CRC).

3. The method of claim 1, further comprising a step of packing a plurality of the data bits into a data word.

4. The method of claim 3, further comprising a step of detecting or correcting error of the data word before correcting the data bit according to the reliability bit.

5. The method of claim 1, further comprising a step of normalizing the at least one reliability bit such that the reliability bit having greater value possesses stronger reliability than the reliability bit having smaller value.

6. The method of claim 1, wherein the step of correcting the error according to the reliability bit comprises:
sorting plural sets of the reliability bits associated with a plurality of the data bits, wherein the sorting is performed according to values of the sets of reliability bits; and
correcting the data bit or bits associated with the set or sets of reliability bits having smaller values than other sets of the reliability bits.

7. The method of claim 6, further comprising a step of comparing a threshold with the plural sets of the reliability bits, such that only the set or sets having value less than the threshold are under sorting.

8. The method of claim 1, wherein the step of generating the at least one reliability bit comprises:
sampling the received data; and
quantizing the sampled data to generate at least one sampled bit associated with each data bit.

9. The method of claim 8, further comprising a step of integrating the sampled data before the sampled data is quantized.

10. The method of claim 1, wherein the step of generating the at least one reliability bit comprises:
sampling the received data to generate at least one sampled bit associated with each data bit; and
hard-deciding each of the at least one sample bit to be one of two logic states.

11. A system of receiving data with enhanced error correction, comprising:
a soft-decision slicer for generating at least one reliability bit associated with each received data bit; and
an enhanced bit error corrector for correcting at least one error of the data bit according to the associated at least one reliability bit.

12. The system of claim 11, wherein the error is corrected with Hamming code, parity code or cyclic redundancy check (CRC).

13. The system of claim 11, further comprising a serial-to-parallel converter for packing a plurality of the data bits into a data word.

14. The system of claim 13, further comprising an error correction control (ECC) processor for detecting or correcting error of the data word before correcting the data bit according to the reliability bit in the enhanced bit error corrector.

15. The system of claim 11, wherein the soft-decision slicer performs:
normalizing of the at least one reliability bit such that the reliability bit having greater value possesses stronger reliability than the reliability bit having smaller value.

16. The system of claim 11, wherein the enhanced bit error corrector performs the steps of:
sorting plural sets of the reliability bits associated with a plurality of the data bits, wherein the sorting is performed according to values of the sets of reliability bits; and
correcting the data bit or bits associated with the set or sets of reliability bits having smaller values than other sets of the reliability bits.

17. The system of claim 16, further comprising a step of comparing a threshold with the plural sets of the reliability bits, such that only the set or sets having value less than the threshold are under sorting.

18. The system of claim 11, wherein the soft-decision slicer comprises:
a sampling switch for sampling the received data; and
a quantizer for quantizing the sampled data to generate at least one sampled bit associated with each data bit.

19. The system of claim 18, further comprising an integrator for integrating the sampled data before the sampled data is quantized.

20. The system of claim 11, wherein the soft-decision slicer comprises:
a sampling switch for sampling the received data to generate at least one sampled bit associated with each data bit; and
a hard-decision slicer for hard-deciding each of the at least one sample bit to be one of two logic states.
